(19) United States
(12) Patent Application Publication
(10) Pub. No.: US 2020/0259083 A1
(43) Pub. Date: Aug. 13, 2020

(54) METHOD FOR FABRICATION OF A CEM DEVICE

(71) Applicant: Arm Limited, Cambridge (GB)

(72) Inventors: Ming He, San Jose, CA (US); Paul Raymond Besser, Sunnyvale, CA (US)

(21) Appl. No.: 16/271,377

(22) Filed: Feb. 8, 2019

(51) Int. Cl. H01L 45/00

(52) U.S. Cl. CPC H01L 45/1616; H01L 45/1625; H01L 45/145; H01L 45/1641; H01L 45/122

(57) ABSTRACT

Disclosed is a method for the fabrication of a correlated electron material (CEM) device to an comprising: forming a layer of a conductive substrate on a substrate; forming a layer of a correlated electron material on the layer of conductive substrate; forming a layer of a conductive overlay on the layer of correlated electron material; patterning these layers to form a stack comprising a conductive substrate, a CEM layer and a conductive overlay on the substrate; forming a cover layer of an insulating material over the stack; and patterning the cover layer wherein: the patterning of the cover layer comprises etching a via in the cover layer whereby to expose a part of the upper surface of the conductive overlay and etching a trench in the cover layer such that the trench surrounds the via.

### BACKGROUND

The present disclosure is concerned with a method for the fabrication of a correlated electron material (CEM) device as well as with an integrated circuit including a CEM device fabricated by the method.

Electronic switching devices are found in a wide variety of electronic device types, such as computers, digital cameras, cellular telephones, tablet devices, personal digital assistants and so forth, where they may function as memory and/or logic devices.

Factors of interest to a designer in considering whether a particular electronic switching device is suitable for such a function, may include physical size, storage density, operating voltages, impedance ranges, and/or power consumption. Other factors of interest may include cost of manufacture, ease of manufacture, scalability and/or reliability. There appears to be an ever-increasing drive towards memory and/or logic devices which can exhibit lower power and/or higher speed. Switching devices comprising a correlated electron material are at the forefront of this drive not just because they can exhibit low power and/or high speed but also because they are generally reliable and easily and cheaply manufactured.

### BRIEF DESCRIPTION OF THE DRAWINGS

Non-limiting embodiments of the present disclosure are described with reference to accompanying drawings in which:

FIG. 1A shows a schematic illustration of a current density versus voltage profile of a CEM switching device according to an embodiment;

FIG. 1B shows a schematic illustration of the CEM switching device of FIG. 1A according to an embodiment;

FIG. 1C shows a schematic diagram of an equivalent circuit for the switching device according to an embodiment;

FIGS. 2A and 2B are schematic illustrations showing cross-section elevation views of part of an integrated circuit comprising a CEM switching device and FIG. 2C is a plan view of that part according to an embodiment;

FIGS. 3A and 3B are schematic illustrations highlighting the problem of under-etch and the problem of over-etch in integrating the device to the circuit of FIGS. 2A, 2B and 2C according to an embodiment;

FIGS. 4A and 4B are schematic illustrations showing cross-section elevation views of part of an integrated circuit according to an embodiment;

FIGS. 5A, 5B, 5C and 5D are schematic illustrations showing steps for forming the part shown in FIGS. 4A and 4B according to an embodiment;

FIGS. 6A and 6B are schematic illustrations showing steps involved for forming the part shown in FIGS. 4A and 4B according to another embodiment; and

FIGS. 7A and 7B are schematic illustrations outlining further steps for forming the part shown in FIGS. 4A and 4B according to an embodiment.

### DETAILED DESCRIPTION

The present disclosure describes an improved CEM device and methods for its manufacture. The CEM device may, in particular, be a switching device. The CEM switching device may find application as a correlated electron random access memory (CERAM) in memory and/or logic devices which may be used with a wide range of electronic circuit types, such as memory controllers, memory arrays, filter circuits, data converters, optical instruments, phase locked loop circuits, microwave and millimeter wave transceivers, and so forth.

A CEM switching device can exhibit a rapid conductor-to-insulator transition as compared to other switching devices because the switching is brought about by an electron correlation rather than by a solid state structural phase change or by formation of filaments, as is found respectively in phase change memory devices and resistive RAM devices.

The rapid conductor-to-insulator transition of a CEM switching device may, in particular, be responsive to a quantum mechanical phenomenon in contrast to the melting/solidification or filament formation found respectively in phase change and resistive RAM devices. The quantum mechanical transition in a CEM switching device between a relatively conductive state and a relatively insulative state (or between a first impedance state and a second impedance state) may occur in several ways.

In one respect, a quantum mechanical transition of a CEM between a relatively insulative/higher impedance state and a relatively conductive/lower impedance state may be understood in terms of a Mott transition.

As used herein, references to a Mott transition are references to traditional Mott transitions (which are described in the literature as purely coulombic) as well as references to Mott-like transitions (in which the coulombic interaction is modified by some other electron interaction, such as a dipole-core charge interaction). Accordingly, a reference to a Mott insulator includes a reference to a charge-transfer (Mott) insulator, such as nickel (II) oxide, in which the columbic interaction or screening is modified by a charge transfer complex through hybridisation with the oxygen band.

In accordance with a Mott transition, a material may switch from a relatively insulative/higher impedance state to a relatively conductive/lower impedance state if a Mott transition condition is satisfied. The Mott criteria may be defined by (n_{c})^{1/3}a≈0.26, wherein n_{c} denotes a concentration of electrons, and wherein “a” denotes the Bohr radius. If a threshold carrier concentration is achieved, such that the Mott criteria is met, the Mott transition is believed to occur. Responsive to the Mott transition occurring, the state of the CEM device changes from a relatively higher resistance/higher capacitance state (e.g., an insulative/higher impedance state) to a relatively lower resistance/lower capacitance state (e.g., a conductive/lower impedance state).

In another respect, the Mott transition may be controlled by a localization of electrons. If carriers, such as electrons, for example, are localized, a strong coulomb interaction between the carriers is believed to split the bands of the CEM to bring about a relatively insulative (relatively higher impedance) state. If electrons are no longer localized, a weak coulomb interaction may dominate, which may give rise to a removal of band splitting, which may, in turn, bring about a metal (conductive) band (relatively lower impedance state) that is substantially dissimilar from the relatively higher impedance state.

The switching from a relatively insulative/higher impedance state to a relatively conductive/lower impedance state may bring about a change in capacitance in addition to a change in resistance. For example, a CEM switch may exhibit a variable resistance together with a property of variable capacitance. In other words, impedance characteristics of a CEM switch may include both resistive and capacitive components. For example, in a metal state, a CEM switch may comprise a relatively low electric field that may approach zero, and therefore may exhibit a substantially low capacitance, which may likewise approach zero.

Similarly, in a relatively insulative/higher impedance state, which may be brought about by a higher density of bound or correlated electrons, an external electric field may be capable of penetrating the CEM and, therefore, the CEM may exhibit higher capacitance based, at least in part, on additional charges stored within the CEM. Thus, for example, a transition from a relatively insulative/higher impedance state to a relatively conductive/lower impedance state in a CEM switch may result in changes in both resistance and capacitance.

A switching device formed from a CEM may exhibit switching of impedance states responsive to a Mott-transition in a majority of the volume of the CEM comprising the device. The CEM may, in particular, form a “bulk switch”. As used herein, the term “bulk switch” refers to at least a majority volume of a CEM switching a device's impedance state, such as in response to a Mott-transition. For example, substantially all CEM of a device may switch from a relatively insulative/higher impedance state to a relatively conductive/lower impedance state or from a relatively conductive/lower impedance state to a relatively insulative/higher impedance state responsive to a Mott-transition.

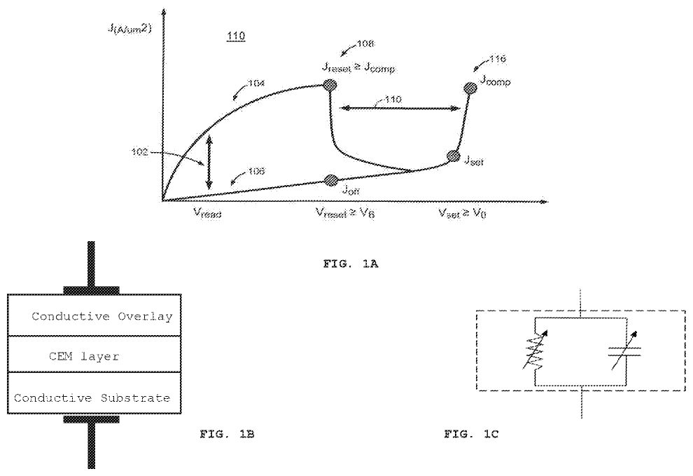

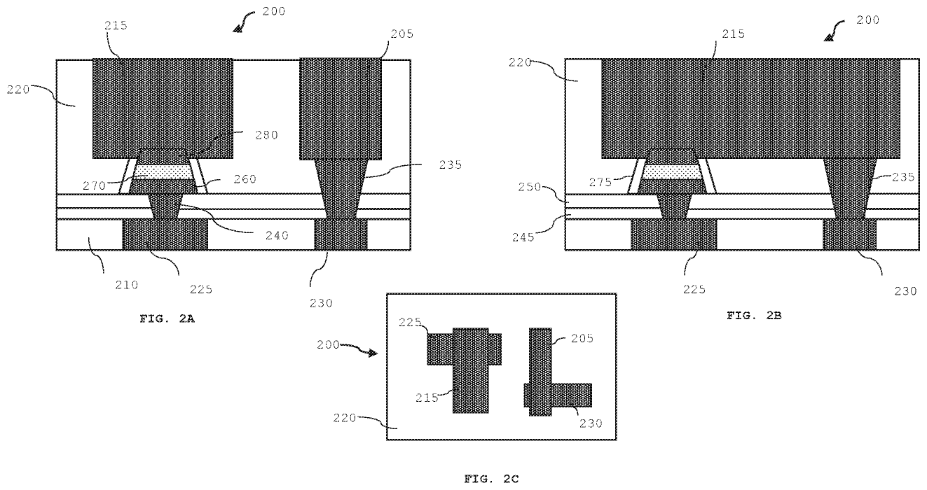

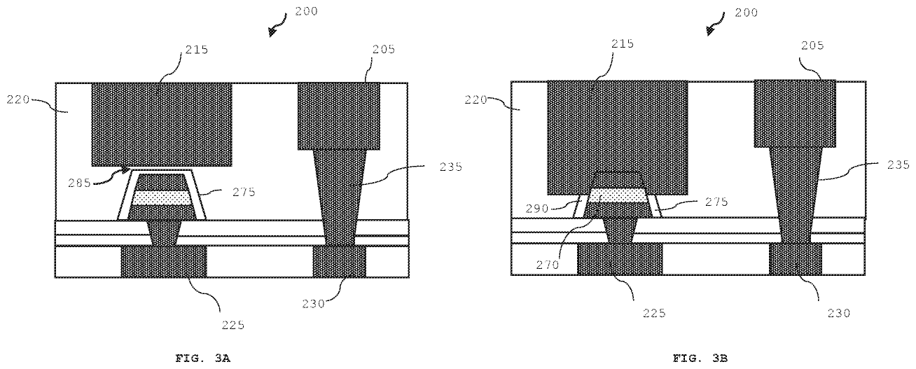

In one arrangement, shown in FIG. 1B, a CEM switching device may comprise a layer of correlated electron material (a CEM layer) sandwiched between a conductive substrate and a conductive overlay. In this arrangement, the CEM switching device can act as memory storage element. In other arrangements, the CEM switching device may comprise either a CEM layer provided on a conductive substrate or a CEM layer provided with a conductive overlay. In these other arrangements, the device comprises source and drain regions providing for a flow of current across the device.

Referring now to FIG. 1A, a current density versus voltage profile 100 of a CEM switching device is shown which illustrates its switching behaviour. Based, at least in part, on a voltage applied to terminals of a CEM device, for example, during a “write operation,” the CEM device may be placed into a relatively low-impedance state or a relatively high-impedance state. For example, application of a voltage Vₛₑₜ and a current density Jₛₑₜ may bring about a transition of the CEM switching device to a relatively low-impedance memory state. Conversely, application of a voltage Vᵣₑₛₑₜ and a current density Jᵣₑₛₑₜ may bring about a transition of the CEM device to a relatively high-impedance memory state.

As shown in FIG. 1A, reference designator 110 illustrates the voltage range that may separate Vₛₑₜ from Vᵣₑₛₑₜ. Following placement of the CEM switching device into a high-impedance state or a low-impedance state, the particular state of the CEM switching device may be detected by application of a voltage V_{read} (e.g., during a read operation) and detection of a current or current density at terminals of the CEM switching device (e.g., utilizing read window 102).

In accordance with FIG. 1A, if sufficient bias is applied (e.g., exceeding a band-splitting potential) and the aforementioned Mott condition is satisfied (e.g., injected electron holes are of a population comparable to a population of electrons in a switching region, for example), a CEM switching device may switch from a relatively low-impedance state to a relatively high-impedance state, for example, responsive to a Mott transition. This may correspond to point 108 of the voltage versus current density profile of FIG. 1A. At, or suitably nearby this point, electrons are no longer screened and become localized near the metal ion. This correlation may result in a strong electron-to-electron interaction potential which may operate to split the bands to form a relatively high-impedance material.

If the CEM switching device comprises a relatively high-impedance state, current may be generated by transportation of electron holes. Consequently, if a threshold voltage is applied across terminals of the CEM device, electrons may be injected into a metal-insulator-metal (MIM) diode over the potential barrier of the MIM device. In certain devices, injection of a threshold current of electrons, at a threshold potential applied across terminals of a CEM device, may perform a “set” operation, which places the CEM device into a low-impedance state. In a low-impedance state, an increase in electrons may screen incoming electrons and remove a localization of electrons, which may operate to collapse the band-splitting potential, thereby giving rise to the low-impedance state.

The current in a CEM switching device may be controlled by an externally applied “compliance” condition, which may be determined at least partially on the basis of an applied external current, which may be limited during a write operation, for example, to place the CEM device into a relatively high-impedance state. This externally-applied compliance current may, in some devices, also set a condition of a current density for a subsequent reset operation to place the CEM device into a relatively high-impedance state. As shown in the particular device of FIG. 1A, a current density J_{comp} applied during a write operation at point 116 to place the CEM switching device into a relatively low-impedance state, may determine a compliance condition for placing the CEM device into a high-impedance state in a subsequent write operation. As shown in FIG. 1A, the CEM device may be subsequently placed into a high-impedance state by application of a current density Jᵣₑₛₑₜ≥J_{comp} at a voltage Vᵣₑₛₑₜ at point 108, at which J_{comp} is externally applied.

The compliance may, in particular, set a number of electrons in a CEM switching device which may be “captured” by holes for the Mott transition. In other words, a current applied in a write operation to place a CEM device into a relatively low-impedance memory state may determine a number of holes to be injected to the CEM device for subsequently transitioning the CEM switching device to a relatively high-impedance memory state.

As pointed out above, a reset condition may occur in response to a Mott transition at point 108. Such a Mott transition may bring about a condition in the CEM switching device in which a concentration of electrons n approximately equals, or becomes at least comparable to, a concentration of electron holes p. This condition may be modeled according to expression (1) as follows:

$${λ}_{TF} {n}^{\frac{1}{3}} = C \sim 0.26 \\ n = {( \frac{C}{{λ}_{TF}} )}^{3} \qquad ( 1 )$$

wherein λ_{TF} corresponds to a Thomas Fermi screening length, and C is a constant.

A current or current density in region 104 of the voltage versus current density profile shown in FIG. 1A, may exist in response to injection of holes from a voltage signal applied across terminals of the CEM switching device. Here, injection of holes may meet a Mott transition criterion for the low-impedance state to high-impedance state transition at current I_{MI} as a threshold voltage V_{MI} is applied across terminals of a CEM device. This may be modeled according to expression (2) as follows:

$${I}_{MI} ( {V}_{MI} ) = \frac{dQ ( {V}_{MI} )}{dt} \approx \frac{Q ( {V}_{MI} )}{t} \\ Q ( {V}_{MI} ) = qn ( {V}_{MI} ) \qquad ( 2 )$$

wherein Q(V_{MI}) corresponds to the charged injected (holes or electrons) and is a function of an applied voltage. Injection of electrons and/or holes to enable a Mott transition may occur between bands and in response to threshold voltage V_{MI}, and threshold current I_{MI}. By equating electron concentration n with a charge concentration to bring about a Mott transition by holes injected by I_{MI} in expression (2) according to expression (1), a dependency of such a threshold voltage V_{MI} on Thomas Fermi screening length λ_{TF} may be modeled according to expression (3), as follows:

$${I}_{MI} ( {V}_{MI} ) = \frac{Q ( {V}_{MI} )}{t} = \frac{qn ( {V}_{MI} )}{t} = \frac{q}{t} {( \frac{C}{{λ}_{TF}} )}^{3} \\ {J}_{reset} ( {V}_{MI} ) = {J}_{MI} ( {V}_{MI} ) = \frac{{I}_{MI} ( {V}_{MI} )}{{A}_{CEM}} = \frac{q}{{A}_{CEM} t} {( \frac{C}{{λ}_{TF}} )}^{3} \qquad ( 3 )$$

wherein A_{CEM} is a cross-sectional area of a CEM switching device; and Jᵣₑₛₑₜ(V_{MI}) may represent a current density through the CEM switching device to be applied to the CEM switching device at a threshold voltage V_{MI}, which may place the CEM switching device into a relatively high-impedance state.

FIG. 1B shows a CEM switching device comprising a CEM layer sandwiched between a conductive substrate and a conductive overlay and FIG. 1C a schematic diagram of an equivalent circuit for the switching device.

As previously mentioned, the CEM switching device may exhibit characteristics of both variable resistance and variable capacitance. In other words, the CEM switching device may be considered as a variable impedance device in which the impedance depends at least in part on resistance and capacitance characteristics of the device if measured across device terminals. The equivalent circuit for a variable impedance device may comprise a variable resistor, such as variable resistor, in parallel with a variable capacitor. Of course, although a variable resistor and variable capacitor are depicted in FIG. 1C as comprising discrete components, the variable impedance device, such as that shown, may comprise a substantially homogenous CEM.

TABLE 1
Correlated Electron Switch Truth Table

| Resistance | Capacitance | Impedance |
|---|---|---|
| R_{high} (V_{applied}) | C_{high} (V_{applied}) | Z_{high} (V_{applied}) |
| R_{low} (V_{applied}) | C_{low} (V_{applied})~0 | Z_{low} (V_{applied}) |

Table 1 illustrates an example truth table for an example variable impedance device, such as the device of FIG. 1A. Table 1 shows that a resistance of a variable impedance device, such as that shown, may transition between a low-impedance state and a substantially dissimilar, high-impedance state as a function at least partially dependent on a voltage applied across the CEM switching device. The impedance exhibited at a low-impedance state may, for example, be approximately in the range of 10.0-100,000.0 times lower than an impedance exhibited in a high-impedance state. However, the impedance exhibited at a low-impedance state may be approximately in the range of 5.0 to 10.0 times lower than an impedance exhibited in a high-impedance state. Table 1 also shows that a capacitance of a variable impedance device, such as the device shown, may transition between a lower capacitance state, which may, for example comprise an approximately zero, or very little, capacitance, and a higher capacitance state that is a function, at least in part, of a voltage applied across the CEM switching device.

The CEM switching device may be placed into a relatively low-impedance memory state, such as by transitioning from a relatively high impedance state, for example, via injection of a sufficient quantity of electrons to satisfy a Mott transition criterion. In transitioning a CEM switching device to a relatively low-impedance state, if enough electrons are injected and the potential across the terminals of the CEM device overcomes a threshold switching potential (e.g., Vₛₑₜ), injected electrons may begin to screen. As previously mentioned, screening may operate to delocalize double-occupied electrons to collapse the band-splitting potential, thereby bringing about a relatively low-impedance state.

In particular embodiments, changes in impedance states of CEM devices, such as changes from a low-impedance state to a substantially dissimilar high-impedance state, for example, may be brought about by “back-donation” of electrons of compounds comprising NiₓO_{y} (wherein the subscripts “x” and “y” comprise whole numbers). As the term is used herein, “back-donation” refers to a supplying of one or more (i.e. electron density) to a transition metal, transition metal oxide, or any combination thereof (i.e. to an atomic orbital of a metal), by an adjacent molecule of a lattice structure (i.e. a ligand), and at the same time donation of electron density from the metal center into an unoccupied antibonding orbital on the ligand/dopant.

The electron back-donating ligand may be a n-back-bonding ligand such as carbonyl (CO), nitrosyl (NO), an isocyanide (RNC where R is H, C₁-C₆ alkyl or C₆-C₁₀-aryl), an alkene (e.g. ethene), an alkyne (e.g. ethyne) or a phosphine such as a trialkyl phosphine or a triaryl phosphine (R₃P wherein R is H, C₁-C₆-alkyl or C₆-C₁₀-aryl), for example triphenylphosphine (PPh₃).

Back-donation may permit a transition metal, transition metal compound, transition metal oxide, or a combination thereof, to maintain an ionization state that is favorable to electrical conduction under an influence of an applied voltage. In certain embodiments, back-donation in a CEM, for example, may occur responsive to use of carbonyl (CO) or a nitrogen-containing dopant, such as ammonia (NH₃), ethylene diamine (C₂H₈N₂), or members of an oxynitride family (NxOy), for example, which may permit a CEM to exhibit a property in which electrons are controllably, and reversibly, “donated” to a conduction band of the transition metal or transition metal oxide, such as nickel, for example, during operation of a device or circuit comprising a CEM. Back donation may be reversed, for example, in nickel oxide material (e.g., NiO:CO or NiO:NH₃), thereby permitting the nickel oxide material to switch to exhibiting a substantially dissimilar impedance property, such as a high-impedance property, during device operation.

Thus, in this context, an electron back-donating material refers to a material that exhibits an impedance switching property, such as switching from a first impedance state to a substantially dissimilar second impedance state (e.g., from a relatively low impedance state to a relatively high impedance state, or vice versa) based, at least in part, on influence of an applied voltage to control donation of electrons, and reversal of the electron donation, to and from a conduction band of the CEM.

In some embodiments, by way of back-donation, a CEM switch comprising a transition metal, transition metal compound, or a transition metal oxide, may exhibit low-impedance properties if the transition metal, such as nickel, for example, is placed into an oxidation state of 2+(e.g., Ni²⁺ in a material, such as NiO:CO or NiO:NH₃). Conversely, electron back-donation may be reversed if a transition metal, such as nickel, for example, is placed into an oxidation state of 1+ or 3+.

Accordingly, during operation of a CEM device, back-donation may result in “disproportionation,” which may comprise substantially simultaneous oxidation and reduction reactions, substantially in accordance with expression (4), below:

2Ni²⁺→Ni¹⁺+Ni³⁺ (4)

Such disproportionation, in this instance, refers to formation of nickel ions as Ni¹⁺+Ni³⁺ as shown in expression (4), which may bring about, for example, a relatively high-impedance state during operation of the CEM device. In an embodiment, a dopant such as a carbon-containing ligand, carbonyl (CO) or a nitrogen-containing ligand, such as an ammonia molecule (NH₃), may permit sharing of electrons during operation of a CEM device so as to give rise to the disproportionation reaction of expression (4), and its reversal, substantially in accordance with expression (5), below:

Ni¹⁺+Ni³⁺→2Ni²⁺ (5)

As previously mentioned, reversal of the disproportionation reaction, as shown in expression (5), permits nickel-based CEM to return to a relatively low-impedance state.

In embodiments, depending on a molecular concentration of NiO:CO or NiO:NH₃, for example, which may vary from values approximately in the range of an atomic concentration of 0.1% to 10.0%, Vᵣₑₛₑₜ and Vₛₑₜ, as shown in FIG. 1A, may vary approximately in the range of 0.1 V to 10.0 V subject to the condition that Vₛₑₜ≥Vᵣₑₛₑₜ. For example, in one possible embodiment, Vᵣₑₛₑₜ may occur at a voltage approximately in the range of 0.1 V to 1.0 V, and Vₛₑₜ may occur at a voltage approximately in the range of 1.0 V to 2.0 V, for example. It should be noted, however, that variations in Vₛₑₜ and Vᵣₑₛₑₜ may occur based, at least in part, on a variety of factors, such as atomic concentration of an electron back-donating material, such as NiO:CO or NiO:NH₃ and other materials present in the CEM device, as well as other process variations, and claimed subject matter is not limited in this respect.

The fabrication of a CEM device into an integrated circuit generally begins with the formation of the device layers by patterning a layer of a conductive substrate, a layer of a correlated electron material and a layer of a conductive overlay which have been deposited on an insulating substrate, such as silica, having one or more embedded interconnects.

The patterning forms a stack from the deposited layers which may be fabricated to full integration in an integrated circuit by depositing a cover layer comprising an insulating material, such as silica, over the stack, patterning the cover layer whereby to form a trench in which the conductive overlay is exposed and depositing a metal interconnect in the trench which contacts the conductive overlay.

Note that the patterning of the cover layer may also comprise forming an additional trench and/or via for the or an additional metal interconnect enabling contact between other devices, such as transistors, at different levels in a 3-dimensional integrated circuit.

One problem with the fabrication of a CEM device to an integrated circuit is that the etching of the trench in the cover layer may not reach the conductive overlay. This under-etch may mean that the interconnect does not contact the conductive overlay when it is deposited in the trench. The failure to form a trench contact with the conductive overlay results in an open circuit.

Another problem with the fabrication of a CEM device to an integrated circuit is that the etching may reach past the conductive overlay. This over-etch may lead to damage of the CEM layer sidewalls as well as an interconnect that contacts the CEM layer when it is deposited in the trench. The over-etch may, therefore, result in an abnormal device having poor switching performance.

The present disclosure relates to a method which avoids these problems by providing for via contact, rather than trench contact, between the conductive overlay and the interconnect in the cover layer.

Accordingly, the present disclosure provides a method for the fabrication of a correlated electron material (CEM) device comprising:

forming a layer of a conductive substrate on a substrate;

forming a layer of a correlated electron material on the layer of conductive substrate;

forming a layer of a conductive overlay on the layer of correlated electron material;

patterning these layers to form a stack comprising a conductive substrate, a CEM layer and a conductive overlay on the substrate;

forming a cover layer of an insulating material over the stack;

and

patterning the cover layer wherein:

the patterning of the cover layer comprises etching a first via in the cover layer to expose a part of the upper surface of the conductive overlay and etching a trench in the cover layer such that the trench surrounds the first via.

The patterning of the cover layer and/or the stack may comprise standard lithographic processes. The patterning of the stack may comprise, for example, forming a hard mask on the layer of the conductive overlay and dry etching the layer of conductive overlay, the layer of correlated electron material and the layer of conductive substrate.

The hard mask may be removed prior to forming the cover layer. Alternatively, it may remain in the stack during the forming of the cover layer and be removed from the stack with the etching of the first via in the cover layer.

The substrate may comprise an insulating material, such as silica, provided on an underlying dielectric material, which includes a via for contacting the conductive substrate with a metal interconnect in the dielectric material. A moisture barrier layer (for example, of silicon nitride (Si₃N₄), silicon carbon nitride (SiCN) or silicon carbide (SiC)) may be provided between the insulating and dielectric materials.

In one embodiment, the method comprises etching the first via prior to etching the trench. In another embodiment, the method comprises etching the first via after etching the first trench.

In any case, the first via and the trench together provide for the deposition of a metal interconnect which contacts the conductive overlay.

When the method comprises etching the first via prior to the trench, it may further comprise depositing a planarization layer on the cover layer which fills the first via whilst the trench is being etched.

Of course, the planarization layer is etched back during the etching of the trench and the part which remains after the etching (that is, the plug in the first via) will be removed prior to deposition of a metal interconnect.

Note that the height (or depth) of the first via depends on the depth of etching of the trench in the cover layer. The other dimensions of the first via will depend on the dimensions of the first via etched in the cover layer. These dimensions may be chosen so that the critical distance (CD) of the first via makes full contact with the upper surface of the conductive overlay.

A relationship which ensures complete enclosure of the first via by the conductive overlay (viz. a landing on the conductive overlay without encroachment around the sides of the conductive overlay) is as follows:

CD (bottom of) via<CD conductive overlay−3σ of overlay error−3σ of bottom via dimension−3σ of conductive overlay CD variation

The method may comprise etching a second via prior to etching the trench. The etching of the second via may comprise etching through the cover layer and a portion of a substrate. The etching provides for a second via contact with a second lower metal interconnect provided in the dielectric material.

The method may comprise etching the trench on top of the first and second vias. Alternatively, it may comprise etching a trench on top of the first via and etching a second trench on top of the second via.

The method may comprise etching the first via prior to, or at the same time as, etching the second via (the conductive overlay providing a good etch stop).

These sequences in etching may require that the patterning of the cover layer uses one or more photoresists and one or more planarization layers which are provided on the cover layer prior to the etching.

Suitable planarization layers and photoresists (negative and positive) will be known to those skilled in the art and may be formed by any appropriate technique, for example, by spin-coating.

Note that when a planarization layer is used for a particular etching step, the etching in the cover layer will etch through the planarization layer (in the selected area) and the remains of the planarization layer is removed after the etching.

The planarization layer should be chosen, therefore, so that it etched back at the same time as the insulating material of the cover layer. The planarization layer may comprise, for example, an organic planarization layer (OPL), a spin-on hard mask (SOH), near frictionless carbon (NFC) layer or a sacrificial light absorbing material (SLAM) layer.

The planarization layers may be removed by exposure to an oxygen (O₂) or carbon dioxide (CO₂) based plasma when it is an organic planarization layer or a spin-on hard mask or by a wet strip using dilute hydrogen fluoride (DHF) when it is a sacrificial light absorbing material.

When the second via is etched after the first via, the method may comprise depositing a first photoresist directly on top of the cover layer and etching the first via. In that case, the method may further comprise removing the first photoresist and depositing a second photoresist on a planarization layer which has been deposited on the cover layer whereby to fill the first via and etching the second via.

When the second via is etched in the cover layer at the same time as the first via aperture, the method may simply comprise depositing a photoresist directly on the cover layer and etching the first via and the second via.

In either case, the method may further comprise depositing a photoresist on a planarization layer which has been deposited on the cover layer whereby to fill the first and second vias and etching the trench or the trenches.

Note that the second via will generally have different dimensions as compared to the first via so a proper optical proximity correction (OPC) sizing will be needed when the first via and the second via are formed at the same time—with account taken of different etch depth and etch bias for each via.

Other embodiments of the method will be apparent to those skilled in the art. For example, when the second via is etched after the first via, the method may comprise depositing a first photoresist on a planarization layer which has been deposited on top of the cover layer and etching the first via.

Further, the method may alternatively comprise etching the first via in a first trench. It may also comprise etching the second via in the first trench or etching first and second vias in respective first and second trenches.

The method may further comprise depositing a metal barrier layer over the conductive overlay and the interior walls of the first via and its trench. The metal barrier layer prevents the migration of metal ion from the metal interconnect into the cover plate and the device. It also protects against the ingress of moisture from ambient or the cover layer to the stack. The metal barrier layer may, in particular, comprise one or more of tantalum nitride (TaN), titanium nitride (TiN), cobalt (Co), ruthenium (Ru) and tantalum (Ta).

Note that when the method comprises etching a second via, the method may also deposit the metal barrier layer over the interior walls of the second via and its trench.

The method may further comprise depositing a moisture barrier layer over the stack prior to the deposition of the cover layer. The barrier layer, which may, for example, comprise silicon nitride (Si₃N₄), silicon carbon nitride (SiCN) or silicon carbide (SiC), prevents the ingress of moisture, for example, from ambient or from the etching of the cover layer, into the sidewalls of the fabricated device.

Note that the moisture barrier layer is etched away from the upper surface (but not the sidewalls) of the conductive overlay when the first via is etched in the cover layer. By contrast, the etching of a trench around the conductive overlay (providing for a trench contact) removes at least a portion of the barrier layer from the sidewalls of the conductive overlay.

When the first and second vias are provided with a single trench, the method may further comprise depositing a metal interconnect whereby to substantially fill the first and second vias and the trench.

When the first and second vias are provided with respective trenches, the method may comprise depositing a first metal interconnect whereby to substantially fill the first via and its trench and depositing a second metal interconnect whereby to substantially fill the second via and its trench.

In any case, the metal interconnect may comprise aluminium, cobalt, tungsten, ruthenium or copper. The deposition of a copper interconnect may, in particular, be carried out by electroplating (with subsequent chemical and/or mechanical polishing).

In embodiments, the method may comprise forming a layer of a correlated electron material comprising a doped metal compound of a d- or f-block element (especially one exhibiting an incomplete d- or f-block shell) such as nickel, cobalt, iron, yttrium or ytterbium. It may comprise forming a CEM layer comprising an oxide of a d- or f-block element and, in particular, a transition metal oxide (TMO) such as nickel oxide, cobalt oxide, iron oxide or an oxide or a rare earth element such as yttrium oxide.

The method may alternatively comprise forming a layer of a correlated electron material comprising a complex (or “mixed”) oxide of d- and/or f-block elements, for example, as a perovskite such as chromium doped strontium titanate, lanthanum titanate, praseodymium calcium manganate or praseodymium lanthanum manganate or a complex oxide or a rare earth element and a transition metal such as yttrium titanium oxide or ytterbium titanium oxide.

The forming of the layer of conductive overlay, the layer of correlated electron material and the layer of conductive substrate may comprise any suitable physical vapour deposition or chemical vapour deposition. In embodiments, the forming of the CEM layer at least comprises a chemical vapour deposition and, in particular, an atomic vapour deposition.

In embodiments, the metal compound of the correlated electron material may be of general formula AB:Lₓ (for example, NiO:CO) wherein the AB denotes, for example, a transition metal compound, such as a transition metal oxide, Lₓ denotes an extrinsic ligand for the metal and x indicates the number of units of ligand for one unit of the transition metal or transition metal compound. The value of x for any specific ligand and any specific combination of ligand with a transition metal oxide may be determined simply by balancing valences.

In embodiments, the method may form a CEM layer comprising doped nickel oxide, such as NiO:Lₓ, wherein the dopant comprising a back-donating ligand comprises a molecule of the form CₐH_{b}N_{d}O_{f} (in which a≥1, and b, d and f≥0) such as: carbonyl (CO), cyano (CN⁻), ethylenediamine (C₂H₈N₂), 1, 10-phenanthroline (C₁₂H₈N₂), bipyridine (C₁₀H₈N₂), pyridine (C₅H₅N), acetonitrile (CH₃CN) and cyanosulfanides such as thiocyanate (NCS⁻).

The forming of the layer of correlated electron material may, in particular, use a physical vapour deposition, such as reactive sputtering, of a transition metal compound, for example, a transition metal oxide, in an atmosphere of a gaseous oxide, such as carbon monoxide (CO).

The forming of the layer of correlated electron material may, in particular, comprise a chemical vapour deposition, such as an atomic layer deposition (ALD), of a transition metal compound, for example, a transition metal oxide.

The atomic layer deposition may form the layer utilising separate precursor molecules AX and BY, according to the expression (6) below:

AX_{(gas)}+BY_{(gas)}=AB_{(solid)}+XY_{(gas)} (6)

wherein “A” of expression (4) corresponds to the transition metal, and “AB” a transition metal compound, such as a transition metal oxide.

The “X” of expression (4) may comprise one or more of an organic or other ligand, such as amidinate (AMD), cyclopentadienyl (Cp), bis(ethylcylcopentadienyl) ((EtCp)₂), bis(pentamethylcyclo-pentadienyl) (C₅(CH₃)₅)₂bis(2,2,6,6-tetramethylheptane-3,5-dionato) ((thd)₂), acetylacetonato (acac), bis(methylcyclopentadienyl) ((MeCp)₂), dimethylglyoximato (dmg)₂, (apo)₂ where apo is 2-amino-pent-2-ene-4-onato, (dmamb)₂ where dmamb is 1-dimethylamino-2-methyl-2-butanolato, (dmamp)₂ where dmamp is 1-dimethylamino-2-methyl-2-propanolato.

Suitable precursor molecules AX include organometallic compounds of the transition metals having one or more of these ligands alone or in combination together with other ligands.

Accordingly, in some embodiments, a nickel based precursor AX (NiX) may comprise, for example, nickel amidinate (Ni(AMD)), bis(cyclopentadienyl)nickel (Ni(Cp)₂), nickel acetoacetonate (Ni(acac)₂), nickel dimethylglyoximate (Ni(dmg)₂), bis(ethylcyclo-pentadienyl)nickel (Ni(EtCp)₂), bis(methylcyclopentadienyl)nickel (Ni(CH₃C₅H₄)₂), bis(pentamethylcyclopentadienyl)nickel (Ni(C₅(CH₃)₅)₂), nickel 2-amino-pent-2-en-4-anato (Ni(apo)₂), Ni(dmamb)₂ where dmamb is 1-dimethylamino-2-methyl-2-butanolato, Ni(dmamp)₂ where dmamp is 1-dimethylamino-2-methyl-2-propanolato.

The precursor “BY” in expression (4) may comprise a gaseous oxide (as an oxidant), such as water (H₂O), oxygen (O₂), ozone (O₃), nitric oxide (NO), nitrous oxide (N₂O) hydrogen peroxide (H₂O₂) or plasma-formed oxygen radical (O.).

In embodiments, the conductive overlay and/or the conductive substrate comprise a major (bulk) layer comprising a conductive metal nitride and a minor layer comprising a noble metal or a conductive metal oxide.

Accordingly, the forming of the layer of conductive substrate comprises depositing a first layer of a metal nitride and depositing a second layer of a noble metal or other conductive material on the first layer. And the forming of the conductive overlay may comprise depositing a first layer of a noble metal or other conductive material and depositing a second layer of a metal nitride on the first layer.

The metal nitride may comprise one or more of titanium nitride, tantalum nitride, and tungsten nitride. The noble metal or other conductive material may comprise platinum, titanium, copper, aluminium, cobalt, nickel, tungsten, cobalt silicide, ruthenium oxide, chromium, gold, palladium, indium tin oxide, tantalum, silver, iridium, iridium oxide or any combination thereof.

The forming of the conductive substrate may be on an insulating substrate, such as a silica. The substrate may include a metal interconnect and a via for contacting the conductive substrate with the metal interconnect.

In one embodiment, the substrate comprises a fluorosilicate glass (FSG) plate including a via for contacting the conductive substrate with a copper interconnect in an underlying dielectric material. A moisture barrier layer comprising silicon nitride (Si₃N₄) may be provided between the dielectric material and the glass plate.

The present disclosure also provides an integrated circuit having a correlated electron material (CEM) device comprising a conductive substrate, a CEM layer and a conductive overlay wherein the device is arranged between an upper metal interconnect provided in a cover layer and a lower metal interconnect provided in a substrate, the lower metal interconnect having a via contact with the conductive substrate, and wherein the upper metal interconnect has a via contact with the conductive overlay.

The present disclosure also provides an electronic device comprising an integrated circuit having a CEM device comprising a conductive substrate, a CEM layer and a conductive overlay wherein the device is provided between an upper metal interconnect and a lower metal interconnect, the lower metal interconnect having a via contact with the conductive substrate, and wherein the upper metal interconnect has a via contact with the conductive overlay.

The present disclosure further provides a CEM device comprising a conductive substrate, a CEM layer and a conductive overlay wherein the device is provided between an upper metal interconnect and a lower metal interconnect, the lower metal interconnect having a via contact with the conductive substrate, and wherein a moisture barrier layer covers substantially the whole of the sidewalls of the conductive substrate, the CEM layer and the conductive overlay.

Embodiments of the integrated circuit, the CEM device and electronic device will be apparent from the foregoing description relating to the method for the fabrication of the device to an integrated circuit.

In particular, a second lower metal interconnect may be provided in the substrate and the upper metal interconnect may have a second via contact with the second lower metal interconnect. The depth of the second via contact may be greater than the depth of the via contact with the conductive overlay. Further, a metal barrier layer may be present between the first and second vias and trench and the upper metal interconnect.

Note that the CEM layer may be interposed between the conductive substrate and the conductive overlay. Note also that the upper metal interconnect may be integrally formed with a via for contacting the conductive overlay.

The fabrication methods, CEM device and integrated circuit according to the present disclosure are described below having regard to non-limiting embodiments and the accompanying drawings.

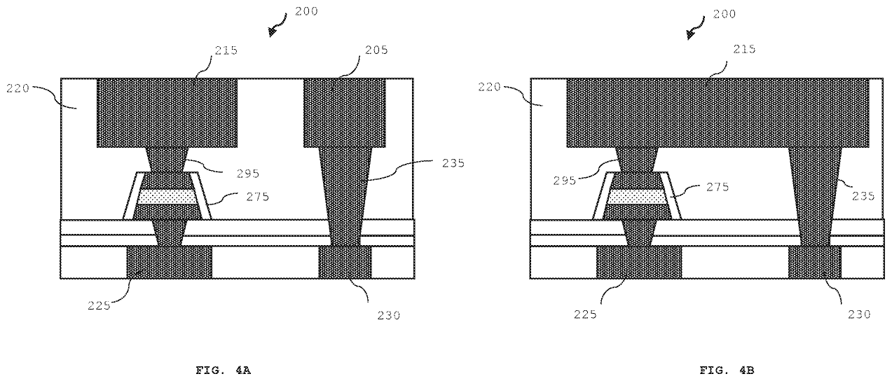

Referring now to FIGS. 2A, 2B and 2C, there are shown cross-section elevation views in FIGS. 2A and 2B, and a plan view in FIG. 2C of a part of an integrated circuit, generally designated 200, in accordance with one embodiment of the present disclosure.

Note that the integrated circuit includes a first upper copper interconnect 215 and a second upper copper interconnect 205 which are embedded in a fluorosilicate glass (FSG) cover plate 220 enclosing a CEM switching device formed on a fluorosilicate glass (FSG) plate 250.

Note that the cross-section side-view (FIG. 2A) and the cross-section elevation view (FIG. 2B) are different because the interconnects 205 and 215 are of similar dimension and position. In the cross-section elevation view interconnect 205 is obscured by interconnect 215 (see FIG. 2C).

The CEM switching device comprises a conductive substrate 260, a CEM layer 270 and a conductive overlay 280 in the form of a stack, formed on a (FSG) glass (SiO₂) plate 250 which is in turn disposed on a lower substrate 210 (comprising low k dielectric material) in which lower copper interconnects 225 and 230 are provided.

A silicon nitride (Si₃N₄) barrier layer 245 is provided between the lower substrate 210 and the glass plate 250. The glass plate 250 and the barrier layer 245 include a via 240 providing contact between the conductive substrate 260 and the copper interconnect 225.

The CEM layer 270 may, in particular, comprise a doped nickel oxide NiO:C as described above. The conductive substrate 260 and the conductive layer 280 may each comprise a first (bulk) layer comprising tantalum nitride (TaN) and a second layer (liner) comprising iridium (not shown). The iridium layer in both the conductive overlay 280 and the conductive substrate 260 contacts the CEM layer 270.

Note that the device is also provided with a moisture barrier layer 275 of silicon nitride (Si₃N₄), for example, which protects the sidewalls of the stack against the ingress of moisture, from for example, the glass cover plate 220.

The barrier layer 275 may cover the conductive overlay 280 when it is deposited but be etched from the upper surface of the conductive overlay 280 during the etching of the via 240.

The copper interconnect 215 occupies a trench in the glass cover plate 220 and surrounds the conductive overlay 280 of the device so that it contacts the upper surface and at least a part of the sidewalls of the conductive overlay 280.

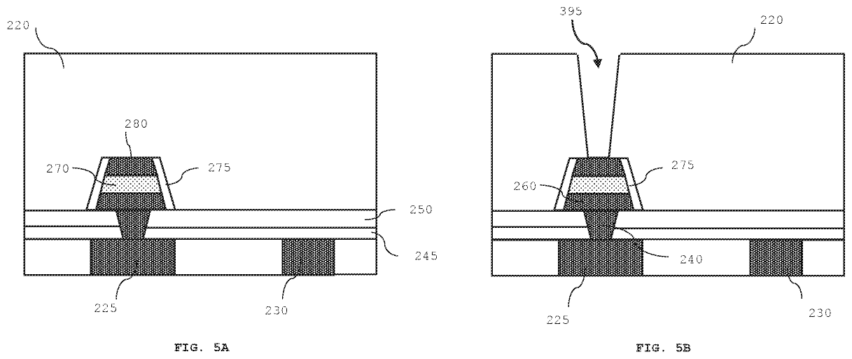

Referring now to FIG. 3A, one problem in forming a trench contact of the type described above is that the etching of the glass cover plate 220 may not reach the conductive layer 280 of the device. This under-etch 285 may result in an open circuit when the copper interconnect 215 is deposited in the trench.

Referring now to FIG. 3B, another problem in forming a trench contact of the type described above is that the etching may reach past the conductive overlay 280 of the device. This over-etch 290 may result in an abnormal device and poor performance through contact of the interconnect 215 with the CEM layer 270.

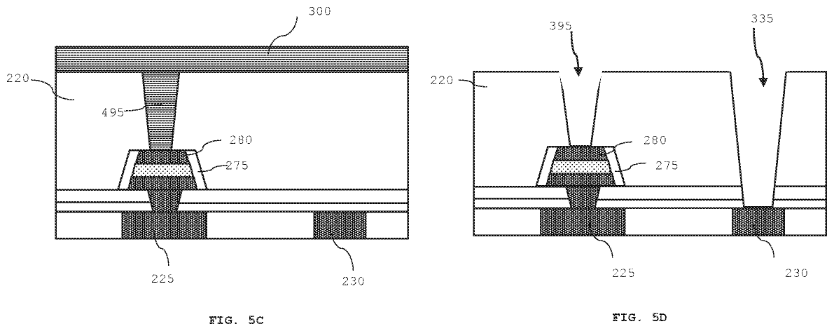

Referring now to FIGS. 4A and 4B, there are shown cross section elevation views of an integrated circuit 200 in which the substrate for the circuit and the copper interconnect 215 are adapted in accordance with the present disclosure to provide a contact with the conductive overlay 260 by means of a via 295. The via 295 provides a full contact on the upper surface of the conductive overlay 280 without encroaching around the sides of the conductive overlay 280.

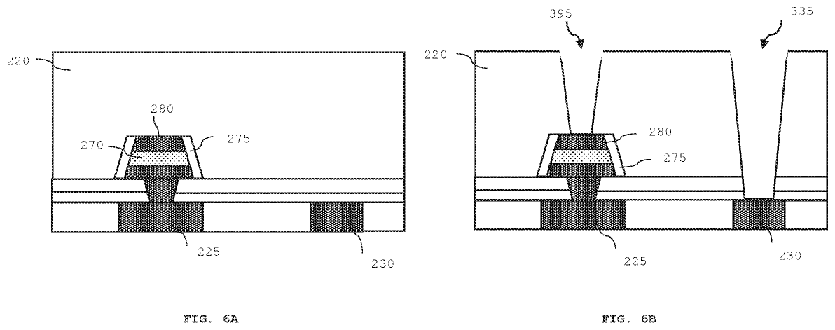

Referring now to FIGS. 5A, 5B, 5C and 5D, there is shown one embodiment for the integration of the stack with the integrated circuit. The (“two color”) integration begins with patterning a trapezoidal aperture 395 in the glass cover plate 220 (see FIGS. 5A and 5B). The etching is carried out using a photoresist (not shown) during a predetermined period or until the etch trace reveals the presence of the material of the conductive overlay 280.

After the etching is complete and the photoresist removed, a planarization layer 300 is deposited over the glass plate 220 so that a portion of the layer 495 fills the via which has been formed in it (see FIG. 5C).

Although it is not generally necessary, the planarization layer 300 may be polished until it has even surface and uniform thickness (at least in the area above the lower copper interconnect 230 embedded in the silicon substrate 210).

The integration is continued by patterning a second aperture in the glass cover plate (and a part of the substrate). The etching is carried out using a photoresist (not shown) during a predetermined period or until the etch trace reveals the presence of copper from the copper interconnect 230.

The remains of the planarization layer 300 are removed following the etching so as to leave a glass cover plate 220 having two trapezoidal vias 395 and 335 of different heights formed within it.

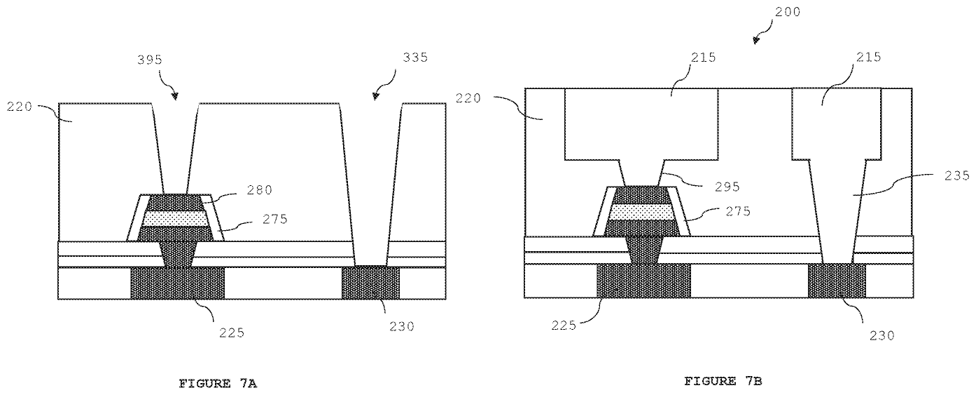

Referring now to FIGS. 6A and 6B, there is shown another embodiment for the integration of the stack with the integrated circuit 205. The (“one color”) integration comprises forming first and second via at the same time.

The patterning uses a single photoresist (not shown) and the etching provides that the first via 395 and the second via 335 have different heights by proper optical proximity correction (OPC) sizing with account taken of different etch depth and etch bias for the two vias.

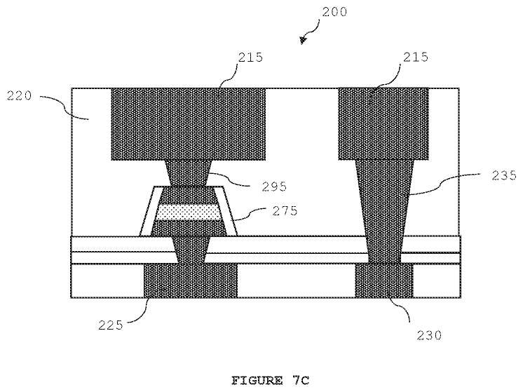

Referring now to FIGS. 7A and 7B, following the removal of the planarization layer 300 or the removal of the photoresist (see FIG. 7A) the patterning is continued by depositing another planarization layer (not shown) over the cover layer and etching the planarization and cover layers so as to form first and second trenches which extend around a respective via 335 or 395.

The etching of the trench may be carried out using a planarization layer filling the first via and the second via within the glass cover plate 220 and the etching carried out during a predetermined period.

After the etching of the trench is complete and the plugs of planarization layer are removed from the apertures 335 and 395, copper interconnects 205 and 215 are deposited in the trench and vias 335 and 395 by electroplating (see FIG. 7B). The deposition is followed by a chemical and/or mechanical polishing so that the upper surface of the interconnect is co-incident with that of the glass cover plate 220.

Note that references herein to a “via” are references to an aperture alone or to an aperture which is filled by a metal interconnect in the cover and/or substrate layer as the context demands.

What is claimed is:

1. A method for the fabrication of a correlated electron material (CEM) device comprising:
forming a layer of a conductive substrate over a substrate;
forming a layer of a CEM over the layer of conductive substrate, the layer of the CEM providing a bulk switch such that a majority volume of the CEM in the layer of the CEM is switchable between impedance states through a reversible electron back-donation;
forming a layer of a conductive overlay over the layer of the CEM;
patterning the layer of the conductive substrate, the layer of the CEM and the layer of the conductive overlay to form a stack comprising a conductive substrate, a CEM layer and a conductive overlay on the substrate;
forming a cover layer of an insulating material over the stack; and
patterning the cover layer wherein:
the patterning of the cover layer comprises etching a first via aperture in the cover layer to expose a part of an upper surface of the conductive overlay and etching a trench aperture in the cover layer such that the trench aperture surrounds the first via aperture.

2. The method according to claim 1, comprising etching the first via aperture prior to etching the trench aperture.

3. The method according to claim 1, comprising etching a second via aperture in the cover layer.

4. The method according to claim 3, comprising etching the second via aperture concurrently with etching the first via aperture.

5. The method according to claim 3, comprising etching the second via aperture after completion of etching the first via aperture and prior to commencement of etching the trench aperture.

6. The method according to claim 3, comprising etching the trench aperture in the cover layer to surround the first via aperture and the second via aperture, or etching a first trench aperture in the cover layer to surround the first via aperture and a second trench aperture in the cover layer to surround the second via aperture.

7. The method according to claim 3, wherein the first via aperture and the second via aperture have different depths in the cover layer.

8. The method according to claim 1, wherein the first via aperture and the trench aperture provide for full contact of an upper metal interconnect over a surface of the conductive overlay.

9. The method according to claim 6, wherein the second via aperture and the second trench aperture provide for full contact of the upper metal interconnect over a surface of a lower metal interconnect within the substrate.

10. The method according to claim 1, further comprising depositing a moisture barrier layer over the stack prior to forming the cover layer.

11. The method according to claim 1, further comprising depositing a metal barrier layer over the conductive overlay and at least the interior walls of the first via aperture and the trench aperture.

12. The method according to claim 11, further comprising depositing a metal interconnect over the conductive overlay and the metal barrier layer in the first via aperture and the trench aperture.

13. An integrated circuit having a correlated electron material (CEM) device comprising a conductive substrate, a CEM layer and a conductive overlay wherein the device is arranged between an upper metal interconnect provided in a cover layer and a lower metal interconnect provided in a substrate, the lower metal interconnect having a via contact with the conductive substrate, and wherein the upper metal interconnect has a via contact with the conductive overlay.

14. An integrated circuit according to claim 13, wherein the upper metal interconnect fully contacts an upper surface of the conductive overlay.

15. An integrated circuit according to claim 13, wherein a second lower metal interconnect is provided in the substrate and the upper metal interconnect has a second via contact with the second lower metal interconnect.

16. An integrated circuit according to claim 13, wherein a moisture barrier layer is present on substantially the whole of the sidewalls of the conductive overlay, the CEM layer and the conductive substrate.

17. An electronic device comprising an integrated circuit having a CEM device comprising a conductive substrate, a CEM layer and a conductive overlay wherein the device is provided between an upper metal interconnect and a lower metal interconnect, the lower metal interconnect having a via contact with the conductive substrate, and wherein the upper metal interconnect has a via contact with the conductive overlay.

18. An electronic device according to claim 17, wherein the upper metal interconnect fully contacts an upper surface of the conductive overlay.

19. An electronic device according to claim 17, wherein a second lower metal interconnect is provided in the substrate and the upper metal interconnect has a second via contact with the second lower metal interconnect.

20. An electronic device according to claim 17, wherein a moisture barrier layer is present on substantially the whole of the sidewalls of the conductive overlay, the CEM layer and the conductive substrate.
